(19) United States
(12) Patent Application Publication
(10) Pub. No.: US 2010/0123237 A1
(43) Pub. Date: May 20, 2010

(54) Semiconductor package of multi stack type

(75) Inventor: Jin-Hee Han, Asan-si (KR)

Correspondence Address: HARNESS, DICKEY & PIERCE, P.L.C., P.O. BOX 8910, RESTON, VA, 20195, US

(73) Assignee: Samsung Electronics Co., Ltd.

(21) Appl. No.: 12/591,342

(22) Filed: Nov. 17, 2009

(30) Foreign Application Priority Data
Nov. 18, 2008 (KR) 10-2008-0114737

(51) Int. Cl. H01L 25/11

(52) U.S. Cl. 257/686; 257/E25.027

(57) ABSTRACT

Provided is a stacked semiconductor package that may include first and second semiconductor packages. The first semiconductor package may include a first package main body and a first lead that includes a first inner lead, a first connection lead, and a first outer lead. The first inner lead may be attached to a bottom part of the first package main body and the first connection lead and the first outer lead may be exposed outside of the first package main body. The second semiconductor package may include a second package main body and a second lead that includes a second inner lead and a second outer lead. The second inner lead may be attached to a bottom part of the second package main body and the second outer lead may be exposed outside of the second package main body. The first and second outer leads may face one another.

### CROSS-REFERENCE TO RELATED APPLICATIONS

This application claims priority under 35 U.S.C. §119 to Korean Patent Application 10-2008-0114737, filed on Nov. 18, 2008, in the Korean Intellectual Property Office (KIPO), the entire contents of which are herein incorporated by reference.

### BACKGROUND

1. Field

Example embodiments relate to a multi-stack type semiconductor package, and more particularly, to a multi-stack semiconductor package capable of providing a relatively stabilized connection and soldering state among leads which may increase inspection efficiency through visual inspection.

2. Description of the Related Art

Electronic devices may require relatively high memory capacity while at the same time require small and lightweight packaging. Stacked semiconductor packages offer relatively high memory capacity, however, limitations associated with the stability of the chips limit the number of chips that may be stacked. Furthermore, in the stacked type semiconductor packages according to the related art, visually inspecting a connection state of solder may be relatively inefficient.

### SUMMARY

Example embodiments provide a semiconductor package of a multi stack type capable of providing a stabilized electrical connection through a horizontal face contact of respective end parts of leads protruded outward from respective semiconductor packages. Leads of pluralities of stacked semiconductor packages may be brought into face-to-face contact with one another and simultaneously soldering defect may be substantially reduced by substantially increasing a soldering area. In particular, pluralities of semiconductor packages of, for example, two stages or more, may be stably stacked.

In accordance with example embodiments, a stacked semiconductor package may include a first semiconductor package and a second semiconductor package. The first semiconductor package may include a first package main body and a first lead. The first lead may include a first inner lead, a first connection lead, and a first outer lead. The first inner lead may be attached to a bottom part of the first package main body and the first connection lead and the first outer lead may be exposed outside of the first package main body. The second semiconductor package may include a second package main body and a second lead. The second lead may include a second inner lead and a second outer lead. The second inner lead may be attached to a bottom part of the second package main body and the second outer lead may be exposed outside of the second package main body. In accordance with example embodiments, the first and second outer leads may face one another.

According to example embodiments, a semiconductor package of a multi stack type may be characterized in that a first semiconductor package and a second semiconductor package are combined, the first semiconductor package being provided by attaching a top face of an inner lead to a bottom face of a package main body and upward bending an end part of the inner lead outward extended to form a connection lead, and by bending in an outward horizontal direction an upper end part of the connection lead, and the second semiconductor package being provided by burying an inner lead in a bottom part of a package main body to expose a bottom face of the inner lead and by extending the inner lead in an outward horizontal direction to form an outer lead in a way a length of end part thereof equals to a length of the outer lead of the first semiconductor package, the second semiconductor package may be stacked on the first semiconductor package through face-to-face contact between the outer leads.

According to example embodiments, a semiconductor package of a multi stack type may be characterized in that first, second, and third semiconductor packages are combined. The first semiconductor package may be provided by attaching a top face of an inner lead to a bottom face of a package main body and upward bending an end part of the inner lead outward extended to form a connection lead, and by bending an upper end part of the connection lead in a horizontal outward direction. The second semiconductor package may be provided by burying an inner lead in a bottom part of a package main body to expose a bottom face of the inner lead and by extending the inner lead in an outward horizontal direction to form an outer lead in a way a length of end part thereof equals to a length of the outer lead of the first semiconductor package. The second semiconductor package may be stacked on the first semiconductor package through face-to-face contact between the outer leads, and the third semiconductor package may be provided by burying an inner lead in a bottom part of a package main body to expose a bottom face of the inner lead and by downward bending an outward-extended end part of the inner lead to form a connection lead. A lower end part of the connection lead may be bent to form an outer lead of a horizontal shape that is brought into face-to-face contact with the outer lead of the second semiconductor package with an equal length.

The inner lead of the first semiconductor package may be configured being attached to a bottom face of the package main body, the inner lead being protruded corresponding to a thickness of the inner lead from the bottom face of the package main body and the bottom face of the inner lead being exposed.

The inner lead of the first semiconductor package may be configured by being buried to a corresponding thickness of the inner lead in a bottom part of the package main body, exposing the bottom face of the inner lead.

The connection lead of the first semiconductor package may be formed in an upward bent shape with a given inclined angle from an end part of the inner lead.

The connection lead of the first semiconductor package may be formed in a vertically upward bent shape from an end part of the inner lead.

The outer lead of the first semiconductor package may have a top face at the same horizontal line level as a top face of the package main body of the first semiconductor package.

The inner lead and the outer lead of the second semiconductor package may be formed at the same horizontal line level as a bottom face of the package main body.

The inner lead of the second semiconductor package may be buried corresponding to a thickness thereof in a bottom part of the package main body, exposing a bottom face of the second semiconductor package.

On the third semiconductor package, a fourth semiconductor package may be stacked in the same shape as that of the third semiconductor package, but a length of connection lead thereof may be relatively more extended and an outer lead of a lower end part thereof may be brought into face-to-face contact with a top face of the outer lead of the third semiconductor package.

A mutual horizontal contact part between end parts of leads may be substantially increased and thus an electrical connection among pluralities of semiconductor packages may be stabilized, substantially reducing connection error.

Quality may be stable through an increased soldering area between leads based on a stabilized solder.

In addition, an inspection by the naked eye is easy through coupling portion and soldering portion exposed to the outside and thus human effort and equipment for the inspection by the naked eye may be substantially reduced.

### BRIEF DESCRIPTION OF THE DRAWINGS

Example embodiments will become more fully understood from the detailed description given hereinbelow and the accompanying drawings which are given by way of illustration and are not limitative of the inventive concept, and wherein:

FIG. 1 is a sectional view of a stacked semiconductor package according to example embodiments;

FIG. 2 is a sectional view of a stacked semiconductor package according to example embodiments;

FIG. 3 is a sectional view of a stacked semiconductor package according to example embodiments;

FIG. 4 is a sectional view of a stacked semiconductor package including three semiconductor packages according to example embodiments;

FIG. 5 is a sectional view of a stacked semiconductor package including three semiconductor packages according to example embodiments; and

FIG. 6 is a sectional view of stacked semiconductor package including four semiconductor packages according to example embodiments.

### DETAILED DESCRIPTION OF EXAMPLE EMBODIMENTS

Example embodiments will now be described more fully with reference to the accompanying drawings, in which example embodiments are shown. The invention may, however, be embodied in different forms and should not be construed as limited to the embodiments set forth herein. Rather, these embodiments are provided so that this disclosure will be thorough and complete, and will fully convey the scope of the invention to those skilled in the art. In the drawings, the sizes of components may be exaggerated for clarity.

It will be understood that when an element or layer is referred to as being “on”, “connected to”, or “coupled to” another element or layer, it can be directly on, connected to, or coupled to the other element or layer or intervening elements or layers that may be present. In contrast, when an element is referred to as being “directly on”, “directly connected to”, or “directly coupled to” another element or layer, there are no intervening elements or layers present. As used herein, the term “and/or” includes any and all combinations of one or more of the associated listed items.

It will be understood that, although the terms first, second, etc. may be used herein to describe various elements, components, regions, layers, and/or sections, these elements, components, regions, layers, and/or sections should not be limited by these terms. These terms are only used to distinguish one element, component, region, layer, and/or section from another element, component, region, layer, and/or section. Thus, a first element, component, region, layer, or section discussed below could be termed a second element, component, region, layer, or section without departing from the teachings of example embodiments.

Spatially relative terms, such as “beneath”, “below”, “lower”, “above”, “upper”, and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” the other elements or features. Thus, the exemplary term “below” can encompass both an orientation of above and below. The device may be otherwise oriented (rotated 90 degrees or at other orientations) and the spatially relative descriptors used herein interpreted accordingly.

Embodiments described herein will refer to plan views and/or cross-sectional views by way of ideal schematic views. Accordingly, the views may be modified depending on manufacturing technologies and/or tolerances. Therefore, example embodiments are not limited to those shown in the views, but include modifications in configuration formed on the basis of manufacturing processes. Therefore, regions exemplified in figures have schematic properties and shapes of regions shown in figures exemplify specific shapes or regions of elements, and do not limit example embodiments.

Example embodiments now will be described more fully hereinafter with reference to the accompanying drawings, in which example embodiments are shown. The inventive concept may, however, be embodied in many different forms and should not be construed as limited to example embodiments. Rather, example embodiments are provided so that this disclosure will be thorough and complete, and will fully convey the inventive scope to those skilled in the art. For clarity, a detailed description for well-known structure and technique of semiconductor devices is omitted. Hereinafter, example embodiments will be described in detail with reference to the accompanying drawings in which like components having like functions have been provided with like reference symbols and numerals.

FIG. 1 is a sectional view of a stacked semiconductor package according to example embodiments. Referring to FIG. 1, a stacked semiconductor package may include a first semiconductor package 10 and a second semiconductor package 20. The first semiconductor package 10 may include a first package main body 11 and a plurality of first leads 12 attached to the first package main body 10. The second semiconductor package 20 may include a second package main body 21 and a plurality of second leads 22 attached thereto. Though not shown in the drawings, the first and second package main bodies 11 and 21 may each include a semiconductor chip, a chip-mounted plate, and a molding resin.

For example, in either of the first and second package main bodies 11 and 21, a semiconductor chip may be attached to chip-mounted plate using a joint member. The semiconductor chip may be fixed by a molding resin. The semiconductor chip may include a memory device and/or logic device, but is not limited thereto. The chip-mounted plate may include a notch formed at an edge portion thereof to increase a combination force with the molding resin. At least a portion of a bottom face of the chip-mounted plate may be exposed from the molding resin.

The plurality of first and second leads 12 and 22 may be individually electrically coupled to the semiconductor chips within the first and second package main bodies 11 and 21, respectively. For example, the first lead 12 may be connected to a semiconductor chip in the first package main body 11 via a wire that may be fixed in the molding resin of the first package main body 11. Similarly, the second lead 22 may be connected to a semiconductor chip in the second package main body 21 via a wire that may be fixed in the molding resin of the second package main body 21. The first and second leads 12 and 22 may be formed to have top faces coupled to the wires. The first and second leads 12 and 22 may also be attached to bottom parts of the first and second package main bodies 11 and 21.

The top face of the first lead 12 may be attached and fixed to the molding resin of the first package main body 11, and the bottom face of the lead 12 may be exposed from the molding resin, and one end of the lead 12 may protrude outside of the molding resin. The protruded portion of the lead 12 may be used as a portion for coupling to another semiconductor package in a stack structure, or may serve as an external terminal.

Considering the structure of the leads, the semiconductor package may be an exposed lead package (ELP), but example embodiments are not limited to the name.

The first and second leads 12 and 22 may include a notch to increase a combination force with molding resin.

As shown in FIG. 1, example embodiments provide a structure wherein a first semiconductor package 10 and a second semiconductor package 20 may be stacked. The first semiconductor package 10 may include a first package main body 11 including a semiconductor chip, a chip-mounted plate, and a wire (not shown). In accordance with example embodiments, the package main body 11 including the semiconductor chip, chip-mounted plate, and wire, may be covered by a molding resin (not shown). Similarly, the second semiconductor package 20 may include a second package main body 21 including a semiconductor chip, a chip-mounted plate, and a wire (not shown). In accordance with example embodiments, the second package main body 21 including the semiconductor chip, the chip-mounted plate, and the wire may be covered by a molding resin (not shown). Further, pluralities of first and second leads 12 and 22 based on different shapes may be individually attached to the first and second package main bodies 11 and 21.

In accordance with example embodiments, the first semiconductor package 10 may be positioned in a lower part of a stacked semiconductor package. Accordingly, the first semiconductor package may be configured to directly contact a wiring line of a circuit board.

For example, the first semiconductor package 10 may include a plurality of first leads 12 which includes a first inner lead 121, a first connection lead 122, and a first outer lead 123. In the first semiconductor package 10, a top face of the first inner lead 121 of the plurality of first leads 12 may be attached to a bottom face of the first package main body 11, and a bottom surface of the first inner lead 121 may be exposed for a connection with the wiring line.

As illustrated in the FIG. 1, the first inner lead 121 may be attached to a bottom part, for example, a bottom face, of the first package main body 11 so that a bottom surface of the first inner lead 121 is exposed from a bottom face of the first package main body 11. The first inner lead 121 may also be attached to the first package main body 11 so that a portion of the first inner lead 121 protrudes by a thickness thereof in a lower direction.

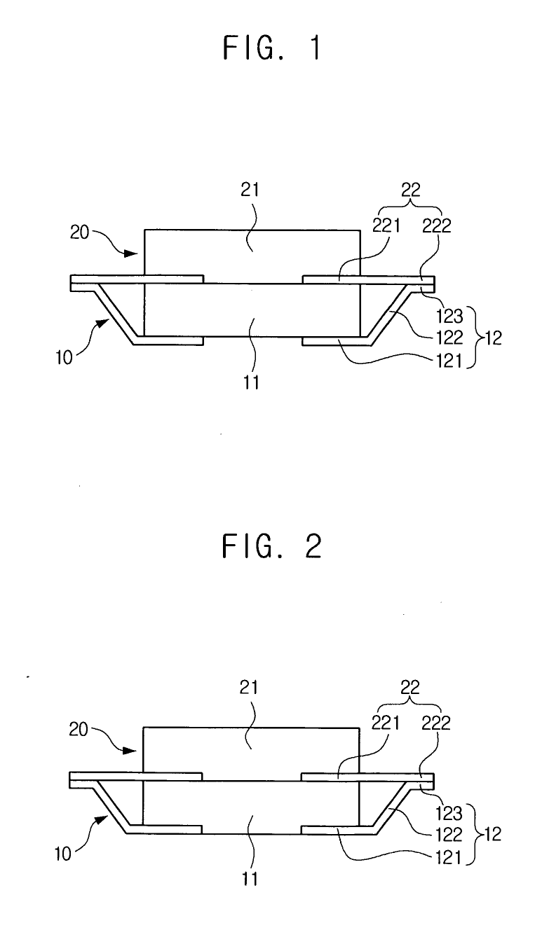

FIG. 2 illustrates a first semiconductor package 10 according to example embodiments. In FIG. 2, the first semiconductor package 10 may be configured so that the first inner lead 121 is buried by a thickness thereof in a bottom part of the first package main body 11.

The first inner lead 121 may be attached to a bottom part of the first package main body 11 so that a portion of the first inner lead 121 may extend outside the first package main body 11 so as to be partially exposed, and this extended part may be bent in an upward direction forming a first connection lead 122. An upper end part of the first connection lead 122 may again be bent in a horizontal outward direction, thus forming a first outer lead 123.

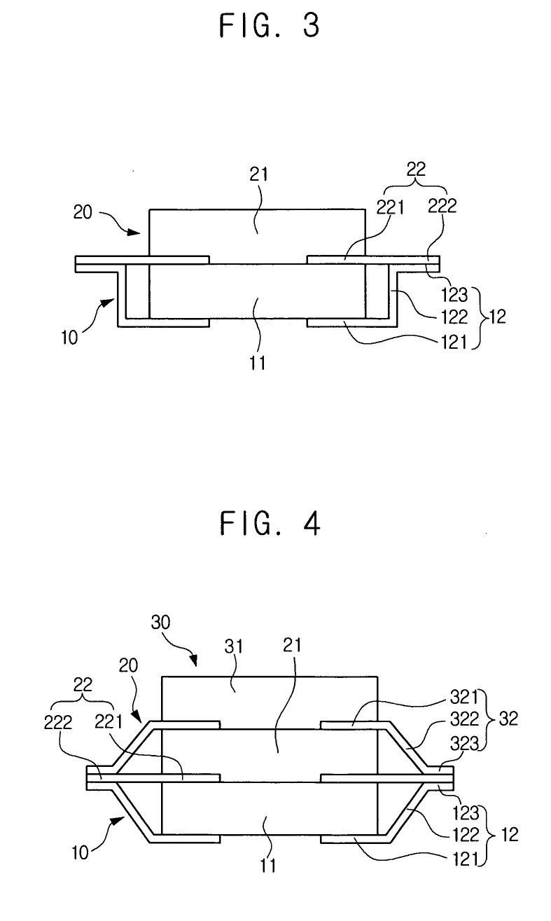

The first connection lead 122 may be bent in a shape of a given inclined angle from an end part of the first inner lead 121 as shown in FIGS. 1 and 2, or may be formed in a shape of vertically bending an end part of the first inner lead 121 as shown in FIG. 3. As shown in FIGS. 1-3, the first outer lead 123 of the first lead 12 in the first semiconductor package 10 may be formed at the same horizontal line level as a top face of the first package main body 11 of the first semiconductor package 10.

The second semiconductor package 20 may be stacked on the first semiconductor package 10 and may be similar to that of the first semiconductor package 10. For example, the semiconductor package 20 may include a second lead 22 that may be attached to a bottom part of second package main body 21. The second semiconductor package 20 may be configured such that the bottom of the second lead 22 is in line with a bottom face of the second package main body 21. As shown in FIGS. 1-3, the second lead 22 of the second semiconductor package 20 may form a straight line shape such that a second inner lead 221 and a second outer lead 222 form a horizontal line. Therefore, the second inner lead 221 attached to the package main body 21 may be formed to extend outward thus exposing a given length thereof to form the second outer lead 222.

In the second package main body 21, a bottom surface of the second inner lead 221 may be exposed, and the second inner lead 221 may be buried corresponding to a thickness of the second lead 22 in a bottom part of the second package main body 21. However, example embodiments are not limited thereto.

A bottom surface of the second inner lead 221 may be buried in the second package main body 21 and may be provided at the same horizontal line as a bottom face of the second package main body 21. Accordingly, face-to-face contact of the second semiconductor package 20 with the first semiconductor package 10 may be stabilized.

The second package main body 21 of the second semiconductor package 20 may be stacked on the first package main body 11 of the first semiconductor package 10, and thus the second outer lead 222 of the second semiconductor package 20 may be brought into face-to-face contact with the first outer lead 123 of the first semiconductor package 10. In accordance with example embodiments, the second outer lead 222 of the second semiconductor package 20 may face the first outer lead 123 of the first semiconductor package 10. Accordingly, the second outer lead 222 of the second semiconductor package 20 may be configured to contact the first outer lead 123 of the first semiconductor package 10. In accordance with example embodiments the first lead 12 may be configured so that the first inner lead 121 and the first connection lead 122 press the first outer lead 123 against the second outer lead 222, however, example embodiments are not limited thereto. For example, the first inner lead 121 and the first connection lead 122 may be configured so that the first outer lead 123 is near to, but does not contact, the second outer lead 222.

FIG. 4 is a sectional view of a stacked semiconductor package according to example embodiments. In FIG. 4, a stacked configuration of first and second semiconductor packages 10 and 20 may be similar to those illustrated in FIGS. 1-3, however, in FIG. 4 at least one third semiconductor package 30 may be stacked on the second semiconductor package 20. In accordance with example embodiments, the addition of a third semiconductor package 30 may achieve a relatively stabilized connection between outer leads.

Because the semiconductor packages 10 and 20 of FIG. 4 may be the same as those illustrated in FIGS. 1-3, a description thereof is briefly described or omitted for convenience. That is, only the differences between FIGS. 1-3 and 4 will be discussed.

In accordance with example embodiments, the second semiconductor package 20 may be stacked on the first semiconductor package 10 that may have a lower part coupled to a wiring line of circuit board. As shown in FIG. 4, contact between the first and second leads 12 and 22 may be obtained, particularly between the first and second outer leads 123 and 222.

Referring to FIG. 4, a third semiconductor package 30 may be stacked on the second semiconductor package 20, thus forming a multi layer package of three layers.

The third semiconductor package 30 may include a third package main body 31 and a third lead 32 therein. In this respect, the third semiconductor package 30 may be similar to the first and second semiconductor packages 10 and 20 described above.

The third package main body 31 of the third semiconductor package 30 may include a semiconductor chip on a chip-mounted plate covered by a molding resin (not shown). Pluralities of third leads 32 may be attached to the third package main body 31, and the respective third leads 32 may be electrically coupled to a semiconductor chip through a wire (not shown). The wire for coupling the semiconductor chip to the third lead 32 may also be covered and fixed by the molding resin covering the semiconductor chip.

As shown in FIG. 4, the third lead 32 of the third semiconductor package 30 may include a third inner lead 321 attached to a bottom part of the package main body 31. The third inner lead 321 may be buried in the bottom part of the third package main body 31 corresponding to a thickness of the lead 32 from the bottom face of the third package main body 31. Thus, a bottom face of the third inner lead 321 of the third semiconductor package 30 may be inline with the same horizontal face as a bottom face of the third package main body 31.

The third inner lead 321 may be extended horizontally in an outward direction of the third package main body 31, and an end part thereof may be bent downward to form a second connection lead 322. A lower end part of the second connection lead 322 may be bent to form a horizontal third outer lead 323. The bent portion of the third inner lead 321 may be at the same position as that of the bent portion of the first inner lead 121 of the first semiconductor package 10. As shown in FIG. 4, the respective first and second connection leads 122 and 322 of the first and third semiconductor packages 10 and 30 may be configured symmetrically with respect to each other in a given inclined angle from the lead 22 of the second semiconductor package 20.

As shown in FIG. 4, the third lead 32 may be configured so that the third inner lead 321 and the second connection lead 322 press the third outer lead 323 against the second outer lead 222, however, example embodiments are not limited thereto. For example, the third lead 32 may be configured so that the third inner lead 321 and the second connection lead 322 position the third outer lead 323 near or against the second outer lead 222.

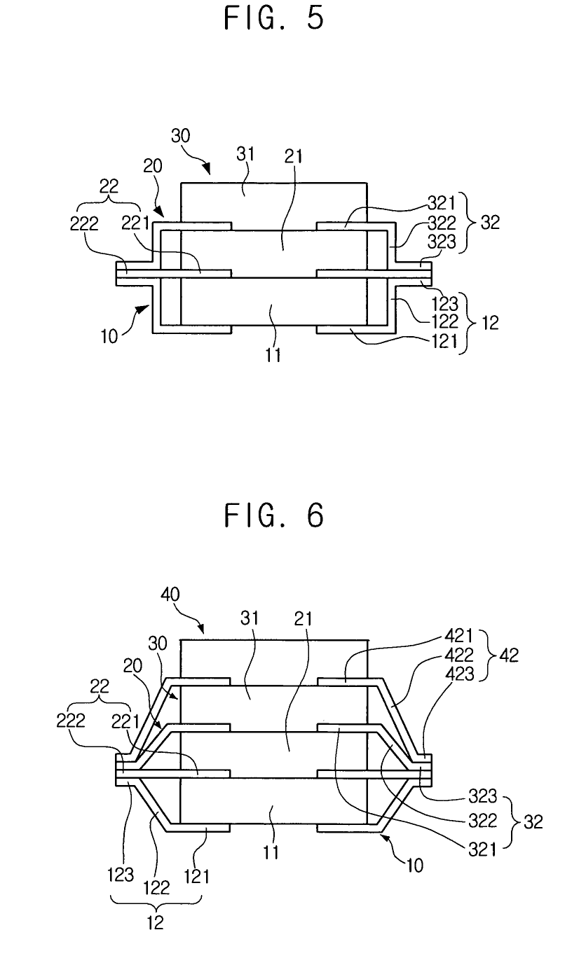

FIG. 5 illustrates a stacked semiconductor package according to example embodiments. The first and second connection leads 122 and 322 of the first and third semiconductor packages 10 and 30 may be individually formed by vertically bending each outer end part of the respective first and third inner leads 121 and 321.

The third outer lead 323 of the third semiconductor package 30 may be close to an upper surface of the second outer lead 222 of the second semiconductor package 20. Similarly, the first outer leads 123 of the first semiconductor package 10 may be close to a lower surface of the second outer lead 222 of the second semiconductor package 20. Accordingly, the outer lead 222 of the second semiconductor package 20 may be sandwiched between the first outer lead 123 of the first semiconductor package 10 and the third outer lead 323 of the third semiconductor package 30. Although the first and third outer leads 123 and 323 have been described as being close to the lower and upper surfaces of the second outer lead 222, example embodiments are not limited thereto. For example, the first outer lead 123 may contact the lower surface of the second outer lead 222 and the third outer lead 323 may contact the upper surface of the second outer lead 222.

FIG. 6 is a sectional view of multi stack type semiconductor package according to example embodiments.

Referring to FIG. 6, a multi stack type semiconductor package may include a first semiconductor package 10, a second semiconductor package 20 stacked on the first semiconductor package 10, a third semiconductor package 30 stacked on the second semiconductor package 20, and a fourth semiconductor package 40 stacked on the third semiconductor package 30. In example embodiments, one stage or more may be formed on the third semiconductor package 30.

The fourth semiconductor package 40 may have a structure similar to that of the third semiconductor package 30. For example, the fourth semiconductor package 40 may include a fourth lead 42 having a fourth inner lead 421, a fourth outer lead 423, and a third connection lead 422. However, in example embodiments, a length of the third connection lead 422 in the fourth lead 42 may be relatively longer than the second connection lead 322 and the inclined angle of the third connection lead 422 may be relatively steeper than the angle used to form the first and second connection leads 122 and 322.

As shown in FIG. 6, the fourth outer lead 423 of the fourth semiconductor package 40 may be close to an upper surface of the third outer lead 323. The third outer lead 323 of the third semiconductor package 30 may be close to an upper surface of the second outer lead 222 of the second semiconductor package 20. Similarly, the first outer leads 123 of the first semiconductor package 10 may be close to a lower surface of the second outer lead 222 of the second semiconductor package 20. Accordingly, the outer lead 222 of the second semiconductor package 20 may be sandwiched between the first outer lead 123 of the first semiconductor package 10 and the third outer lead 323 of the third semiconductor package 30. Furthermore, the third outer lead 323 may be sandwiched between the second outer lead 222 and the fourth outer lead 423. Although the first and third outer leads 123 and 323 have been described as being close to the lower and upper surfaces of the second outer lead 222 and the fourth outer lead 423 has been described as being close to the upper surface of the third outer lead 323, example embodiments are not limited thereto. For example, the first outer lead 123 may contact the lower surface of the second outer lead 222 and the third outer lead 323 may contact the upper surface of the second outer lead 222. Furthermore, the fourth outer lead 423 may contact the upper surface of the third outer lead 323.

In example embodiments described above, the leads may be protruded outward from the semiconductor package, forming a face-to-face contact at one point and thus obtaining an electrical contact in a stabilized connection state and increased reliability for the electrical connection.

In addition, pluralities of outer leads coupled through the face-to-face contact may be soldered at a time and a soldered area may be substantially increased, thereby substantially reducing error in a soldering process.

In particular, a portion of the outer leads as the soldered portion may be entirely exposed to the outside and an outer visual inspection for the connection state may be relatively easy.

Further, in example embodiments, even though the number of stacked-packages of a stacked semiconductor package increases, the stacked semiconductor package may be realized relatively thinly.

It will be apparent to those skilled in the art that modifications and variations may be made without deviating from the spirit or scope of the inventive concept. Thus, it is intended that the inventive concept cover any such modifications and variations of the inventive concept provided they come within the scope of the appended claims and their equivalents.

In the drawings and specification, there have been disclosed typical embodiments of the inventive concept and, although specific terms are employed, they are used in a generic and descriptive sense just and not for limitation, the scope of the inventive concept being set forth in the following claims.

What is claimed is:

1. A stacked semiconductor package, comprising:
a first semiconductor package including a first package main body and a first lead, the first lead including a first inner lead, a first connection lead, and a first outer lead, the first inner lead being attached to a bottom part of the first package main body and the first connection lead and the first outer lead being exposed outside of the first package main body; and
a second semiconductor package including a second package main body and a second lead, the second lead including a second inner lead and a second outer lead, the second inner lead being attached to a bottom part of the second package main body and the second outer lead being exposed outside of the second package main body, wherein the first and second outer leads face one another.

2. The package of claim 1, wherein the first inner lead of the first semiconductor package is attached to a bottom face of the first package main body so that a bottom surface of the first inner lead protrudes from the bottom face of the first package main body.

3. The package of claim 1, wherein the first inner lead of the first semiconductor package is buried corresponding to a thickness of the first inner lead in the bottom part of the first package main body such that a bottom surface of the first inner lead is exposed.

4. The package of claim 1, wherein the first connection lead of the first semiconductor package has an upward-bent shape with an inclined angle from an end part of the first inner lead.

5. The package of claim 1, wherein the first connection lead of the first semiconductor package has an upward vertical-bent shape from an end part of the first inner lead.

6. The package of claim 1, wherein the first outer lead of the first semiconductor package includes a horizontal top face at the same horizontal line level as a horizontal top face of the first package main body of the first semiconductor package.

7. The package of claim 6, wherein the second inner lead and the second outer lead of the second semiconductor package have a horizontal bottom face at the same horizontal line level as a bottom face of the second package main body of the second semiconductor package.

8. The package of claim 7, wherein the horizontal top face of the first outer lead of the first semiconductor package and the horizontal bottom face of the second inner lead face are at the same horizontal line level.

9. The package of claim 1, further comprising:
a third semiconductor package stacked on the second semiconductor package, the third semiconductor package including a third package main body and a third lead, the third lead including a third inner lead, a second connection lead, and a third outer lead, the third inner lead being attached to a bottom part of the third package main body and the second connection lead and the third outer lead being exposed outside of the third package body, the first, second, and third outer leads facing each other.

10. The package of claim 9, wherein the first outer lead of the first semiconductor package includes a horizontal top face at the same horizontal line level as a bottom horizontal face of the second outer lead, and the third outer lead of the third semiconductor package includes a horizontal bottom face at the same horizontal line level as a top face of the second outer lead.

11. The package of claim 9, wherein
the first connection lead of the first semiconductor package has an upward-bent shape with a first inclined angle from an end part of the first inner lead and the second connection lead of the third semiconductor package has a downward-bent shape with a second inclined angle from an end part of the third inner lead.

12. The package of claim 11, wherein the first and second angles are substantially the same and a length of the first connection lead and a length of the second connection lead are substantially the same.

13. The package of claim 12, wherein the first and second connection leads are symmetrical with respect to the second outer lead.

14. The package of claim 9, wherein the first connection lead of the first semiconductor package has an upward vertical-bent shape from an end part of the inner lead and the second connection lead of the third semiconductor package has a downward vertical-bent shape from an end part of the third inner lead of the third semiconductor package.

15. The package of claim 14, wherein a length of the first connection lead and a length of the second connection lead are substantially the same.

16. The package of claim 15, wherein the first and second connection leads are symmetrical with respect to the second outer lead.

17. The package of claim 9, further comprising:
a fourth semiconductor package stacked on the third semiconductor package, the fourth semiconductor package including a fourth package body and a fourth lead, the fourth lead including a fourth inner lead, a third connection lead, and a fourth outer lead, the fourth inner lead being attached to a bottom part of the fourth package main body and the fourth outer lead and the third connection lead being exposed outside of the fourth package main body, wherein the first, second, third, and fourth outer leads face each other.

18. The package of claim 17, wherein
the first connection lead of the first semiconductor package has an upward-bent shape with a first inclined angle from an end part of the first inner lead, the second connection lead of the third semiconductor package has a downward-bent shape with a second inclined angle from an end part of the third inner lead, and the third connection lead of the fourth semiconductor package has a downward-bent shape with a third inclined angle from an end part of the fourth inner lead.

19. The package of claim 18, wherein the first and second angles are substantially the same and a length of the first connection lead and a length of the second connection lead are substantially the same and a length of the third connection lead is longer than either of the lengths of the first and second connection leads.

20. The package of claim 17, wherein the first outer lead of the first semiconductor package includes a horizontal top face at the same horizontal line level as a bottom horizontal face of the second outer lead, the third outer lead of the third semiconductor package includes a horizontal bottom face at the same horizontal line level as a top face of the second outer lead, and the fourth outer lead of the fourth semiconductor package includes a bottom face at the same horizontal line level as a top face of the third outer lead.
